(19) United States
(12) Patent Application Publication
(10) Pub. No.: US 2008/0214015 A1
(43) Pub. Date: Sep. 4, 2008

(54) Semiconductor devices and methods of manufacture thereof

(76) Inventor: Tim Boescke, Dresden (DE)

Correspondence Address: SLATER & MATSIL LLP, 17950 PRESTON ROAD, SUITE 1000, DALLAS, TX, 75252, US

(21) Appl. No.: 11/713,498

(22) Filed: Mar. 2, 2007

(51) Int. Cl. H01L 21/31

(52) U.S. Cl. 438/758

(57) ABSTRACT

Semiconductor devices and methods of manufacture thereof are disclosed. In one embodiment, a method of fabricating a semiconductor device includes providing a workpiece, and forming a dielectric material over the workpiece. Forming the dielectric material includes forming a first layer of a first material and forming a second layer of a second material. The first material includes AO₂, wherein A includes at least one Group IVB element. The second material includes BₓO_{y}, wherein B includes at least one Group 1A, IIA, IIIA, IIIB, or Lanthanide series element.

### BACKGROUND

Generally, semiconductor devices are used in a variety of electronic applications, such as computers, cellular phones, personal computing devices, and many other applications. Home, industrial, and automotive devices that in the past comprised only mechanical components now have electronic parts that require semiconductor devices, for example.

Semiconductor devices are manufactured by depositing many different types of material layers over a semiconductor workpiece or wafer, and patterning the various material layers using lithography. The material layers typically comprise thin films of conductive, semiconductive, and insulating materials that are patterned and etched to form integrated circuits (IC's). There may be a plurality of transistors, memory devices, switches, conductive lines, diodes, capacitors, logic circuits, and other electronic components formed on a single die or chip.

Insulating materials comprise dielectric materials that are used in many types of semiconductor devices. Silicon dioxide (SiO₂) is a common dielectric material used in semiconductor device manufacturing, for example, which has a dielectric constant or k value of about 3.9. Some semiconductor applications require the use of a high k dielectric material having a higher k value than the k value of silicon dioxide, for example. Some transistors require a high k dielectric material as a gate dielectric material, and some capacitors require a high k dielectric material as an insulating material between two conductive plates, as examples, to reduce leakage current and increase capacitance.

A dynamic random access memory (DRAM) is a memory device that can be used to store information. A DRAM cell in a memory array typically includes two elements: a storage capacitor and an access transistor. Data can be stored into and read out of the storage capacitor by passing a charge through the access transistor and into the capacitor. The capacitance, or the amount of charge held by the capacitor per applied voltage, is measured in farads and depends upon the area of the plates, the distance between them, and the dielectric value of the insulator, as examples.

High k dielectric materials are typically used as an insulating material in the storage capacitor of DRAM cells or as a gate dielectric in transistors. High-k dielectric materials are typically used in conjunction with metal electrodes. Some examples of high k dielectric materials are HfO₂, ZrO₂, and TiO₂. However, these dielectric materials exhibit a Fermi-level pinning effect in some applications. A Fermi-level pinning effect can occur at the interface of a conductive material and a dielectric material. Fermi-level pinning causes an increased charge in the dielectric material, which causes a change of the band alignment and a change in the observed effective work function of the metal.

In electronics, the term “work function” refers to the energy (usually measured in electron volts) needed to remove an electron from the Fermi level to a point an infinite distance away outside the surface. The work function of a semiconductor or conductor directly affects the threshold voltage of a transistor when the material is used as a gate electrode, for example. The work function also affects the band offset of the dielectric material and the electrode material of a memory capacitor and thus also affects the electronic leakage current through a capacitor. However, Fermi-level pinning caused by the use of high k gate dielectric materials as a gate dielectric or capacitor dielectric pins or fixes the work function.

What are needed in the art are improved high dielectric constant (k) dielectric materials and methods of formation thereof in semiconductor devices.

### SUMMARY OF THE INVENTION

These and other problems are generally solved or circumvented, and technical advantages are generally achieved, by preferred embodiments of the present invention, which provide improved methods of forming high k dielectric materials and structures thereof.

In accordance with a preferred embodiment of the present invention, a method of fabricating a semiconductor device includes providing a workpiece, and forming a dielectric material over the workpiece. Forming the dielectric material includes forming a first layer of a first material and forming a second layer of a second material. The first material includes AO₂, wherein A includes at least one Group IVB element. The second material includes BₓO_{y}, wherein B includes at least one Group 1A, IIA, IIIA, IIIB, or Lanthanide series element.

The foregoing has outlined rather broadly the features and technical advantages of embodiments of the present invention in order that the detailed description of the invention that follows may be better understood. Additional features and advantages of embodiments of the invention will be described hereinafter, which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 shows a cross-sectional view of a semiconductor device including a novel high k dielectric material in accordance with a preferred embodiment of the present invention;

FIG. 2 shows a more detailed view of the high k dielectric material of FIG. 1 that includes a first material and a second material disposed over the first material in accordance with a preferred embodiment of the present invention;

FIG. 3 shows a more detailed view of the high k dielectric material of FIG. 1 that includes a second material and a first material disposed over the second material in accordance with a preferred embodiment of the present invention;

FIG. 4 shows a more detailed view of the high k dielectric material of FIG. 1 that includes a single layer of a third material in accordance with a preferred embodiment of the present invention;

FIG. 5 shows a more detailed view of the high k dielectric material of FIG. 1 that includes a third material and a fourth material disposed over the third material in accordance with a preferred embodiment of the present invention;

FIG. 6 shows a more detailed view of the high k dielectric material of FIG. 1 that includes a first layer of the first material, a second layer of a second material disposed over the first layer of the first material, and a third layer of the first material disposed over the second layer of the second material in accordance with a preferred embodiment of the present invention;

FIG. 7 shows the semiconductor device of FIG. 1 after a layer of conductive material has been formed over the high k dielectric material;

FIG. 8 shows an embodiment of the present invention where a layer of conductive material is disposed beneath the high k dielectric material;

FIG. 9 shows a cross-sectional view of a semiconductor device, wherein the novel high k dielectric materials of embodiments of the present invention are implemented in a transistor structure;

FIGS. 10 and 11 show cross-sectional views of a semiconductor device at various stages of manufacturing, wherein the novel high k dielectric materials of embodiments of the present invention are implemented in a DRAM structure; and

FIG. 12 shows a cross-sectional view of a semiconductor device at various stages of manufacturing, wherein the novel high k dielectric materials of embodiments of the present invention are implemented in a metal-insulator-metal (MIM) capacitor structure.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

Metals that exhibit a high vacuum work function show a much lower work function when brought into contact with HfO₂/ZrO₂ based dielectric materials, due to the Fermi-level pinning effect, after annealing in high temperatures. One cause of the Fermi-level pinning effect is the generation of oxygen vacancies in the HfO₂/ZrO₂ dielectric material. The generated oxygen vacancies are usually positively charged, reducing the observed work function. A negative charge can also be produced due to electron capture, which may play a role in the mid-gap shift of N type materials when the Fermi-level of a metal electrode traps the energy level.

Embodiments of the present invention achieve technical advantages by reducing the amount of Fermi-level pinning of a conductive material, by forming a high k dielectric material that includes at least one dopant or element having a larger cationic radius than atoms of a tetravalent oxide in the high k dielectric material. The Fermi-level pinning effect is reduced by the introduction of charge compensated oxygen vacancies, leading to a reduction of charged oxygen vacancies in the dielectric material.

The present invention will be described with respect to preferred embodiments in specific contexts, namely in the formation of high k dielectric materials and electrodes in semiconductor devices such as capacitors and transistors. The invention may also be applied, however, to the formation of dielectric materials in other applications where high k dielectric materials are required, for example, and in other applications where conductive materials are formed adjacent to insulating materials.

FIG. 1 shows a cross-sectional view of a semiconductor device 100 including a novel high k dielectric material 104 in accordance with a preferred embodiment of the present invention. The semiconductor device 100 is preferably fabricated by providing a workpiece 102, as shown in FIG. 1. The workpiece 102 may include a semiconductor substrate comprising silicon or other semiconductor materials covered by an insulating layer, for example. The workpiece 102 may also include other active components or circuits, not shown. The workpiece 102 may comprise silicon oxide over single-crystal silicon, for example. The workpiece 102 may include other conductive layers or other semiconductor elements, e.g., transistors, diodes, etc. Compound semiconductors, GaAs, InP, Si/Ge, SiGe, or SiC, as examples, may be used in place of silicon. The workpiece 102 may comprise a silicon-on-insulator (SOI) substrate, for example.

A high k dielectric material 104 is formed over the workpiece 102, as shown in FIG. 1. The high k dielectric material 104 preferably comprises a dielectric constant or k value of greater than 3.9, for example. The high k dielectric material 104 preferably comprises a thickness d₁ of about 200 Angstroms or less. The high k dielectric material 104 may comprise a thickness of about 10 to 40 Angstroms in some embodiments, such as in transistor applications, and the high k dielectric material 104 may comprise a thickness of about 50 to 100 Angstroms in other embodiments, such as in capacitor applications, as examples. Alternatively, the high k dielectric material 104 may comprise other dimensions.

The high k dielectric material 104 preferably comprises an oxide of at least one tetravalent element, for example. The tetravalent element is also referred to herein as A. The oxide of the at least one tetravalent element A preferably comprises an oxide of an element from Group IVB of the period table of elements. The oxide of the at least one tetravalent element A preferably comprises an oxide of Zr, Hf, or Ti, for example, although alternatively, the oxide may comprise other materials. The oxide may comprise one, or more than one, element A, for example.

The high k dielectric material 104 preferably also includes at least one dopant. The at least one dopant is also referred to herein as B. The at least one dopant B preferably comprises an element having an atom that has a larger size than the atom of the at least one tetravalent element A, for example. In particular, the element B preferably comprises an atom having a larger cationic radius than the cationic radius of the atom of element A, in accordance with embodiments of the present invention. The at least one dopant B preferably comprises one or more elements from Group 1A, IIA, IIIA, or IIIB of the periodic table of elements, for example. The at least one dopant B may comprise a trivalent element in Group IIIA, Group IIIB or the Lanthanide series larger than Hf, Zr, or Ti, such as Y, La, Pr, Nd, Pm, Sm, Eu, Gd, Tb, Dy, Ho, Er, Tm, Yb, Lu, Sc, In, Tl, or other elements, as examples. The at least one dopant B may comprise a divalent element in Group IIA larger than Hf, Zr, or Ti, such as Mg, Ca, Sr, Ba, or other elements, as examples. The at least one dopant B may comprise a monovalent element in Group 1A larger than Hf, Zr, or Ti, such as Li, Na, K, Rb, Cs, or other elements, as examples. The at least one dopant B may comprise one, or more than one, of the elements previously listed, for example.

If the at least one dopant B comprises In, Ti, Ba, Na, K, Rb, or Cs, the workpiece 102 preferably comprises a semiconductor material other than silicon, because these particular elements may be thermodynamically unstable on silicon in some applications, for example. The workpiece 102 in these embodiments may comprise a semiconductive material such as GaAs, InP, InSb, SiGe, Ge, GaP, GaN, or ZnS, as examples, although other materials may also be used for the workpiece 102.

The dopant or element B of the high k dielectric material 104 may comprise an oxide of the dopant or element B, or the dopant or element B may be doped into another oxide material. If the dopant or element B is doped into the high k dielectric material 104, the dopant concentration of B is preferably about 5 to 50 in molecular percent of the high k dielectric material 104, for example, although alternatively, other concentrations may also be used.

The high k dielectric material 104 preferably comprises a material that reduces a Fermi-pinning effect of a subsequently deposited conductive material, to be described further herein. While the atoms of the element A introduces charged oxygen vacancies in the high k dielectric material, advantageously, the larger atoms of the element B having a larger cationic radius than the cationic radius of the element A atoms in the high k dielectric material 104 reduce the number of the charged oxygen vacancies introduced by element A in the high k dielectric material 104, preventing oxygen from moving into a subsequently-deposited conductive material (such as conductive material 114 shown in FIG. 7, to be described further herein).

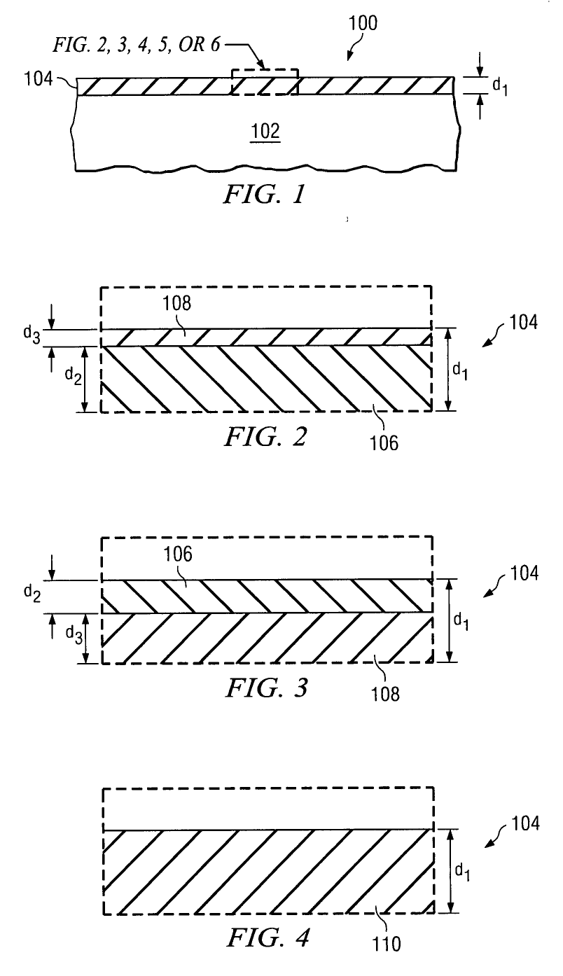

FIGS. 2 through 6 show more detailed views of the high k dielectric material 104 shown in FIG. 1 in accordance with preferred embodiments of the present invention. In a first embodiment, the high k dielectric material 104 comprises a first layer of a first material 106 disposed over the workpiece 102, as shown in FIG. 2. The first material 108 is preferably formed directly over, abutting, and adjacent to the workpiece 102, as shown. A second layer of a second material 108 is disposed over the first material 106. The first material 106 preferably comprises a thickness d₂ of about 195 Angstroms or less. The second material 108 preferably comprises a thickness d₃ of about 30 Angstroms or less, e.g., about 5 to 30 Angstroms. The first material 106 and the second material 108 may comprise different thicknesses d₂ and d₃, or the first material 106 and the second material 108 may comprise the same thickness, e.g., d₂ may be substantially equal to d₃. The first material 106 and the second material 108 may both comprise a thickness d₂ and d₃ of about 50 Angstroms or less, in some embodiments. Forming the first layer of the first material 106 and forming the second layer of the second material 108 may comprise forming material layers each having a thickness of about 200 Angstroms or less, in other embodiments. Alternatively, the first material 106 and the second material 108 may comprise other dimensions, for example.

The first material 106 preferably comprises a material comprising AO₂, wherein A comprises a tetravalent element such as Zr, Hf, Ti, or combinations thereof. The second material 108 preferably comprises a material comprising BₓO_{y}, wherein B comprises an element from Group 1A, IIA, IIIA, IIIB, or the Lanthanide series, such as Y, La, Pr, Nd, Pm, Eu, Gd, Th, Dy, Ho, Er, Tm, Yb, Lu, Sc, In, Tl, Mg, Ca, Sr, Ba, Li, Na, K, Rb, Cs, or combinations thereof, and wherein x and y indicate the stoichiometry of the second material 108, e.g., the amount of the at least one element B and the amount of oxygen O in the second material 108, for example. The at least one element B is also referred to herein as a dopant.

As an example, the first material 106 may comprise ZrO₂, and the second material 108 may comprise GdₓO_{y}. The second material 108 may be doped with the at least one element B, or the second material 108 may comprise an oxide of the at least one element B, for example, in accordance with embodiments of the present invention. Alternatively, the second material 108 may comprise an oxide of at least one element B, and the second material 108 may also be doped with another, different, at least one element B, in other embodiments of the present invention.

In a second embodiment, the second material 108 is formed first. The first material 106 is preferably disposed over the second material 108 which is formed directly over, abutting, and adjacent to the workpiece 102, as shown in FIG. 3. The first material 106 and the second material 108 preferably comprise the same materials and dimensions as previously described for the embodiment shown in FIG. 2, for example.

FIG. 4 shows a more detailed view of the high k dielectric material 104 of FIG. 1 in accordance with a third embodiment of the present invention. The high k dielectric material 104 includes a single layer of a third material 110 in this embodiment. The third material 110 preferably comprises a thickness d₁ of about 200 Angstroms or less in this embodiment. The third material 110 is preferably formed directly over, abutting, and adjacent to the workpiece 102, as shown. The third material 110 preferably comprises a material comprising AₓB_{y}O_{z}, wherein A comprises a Group IVB element such as Zr, Hf, Ti, or combinations thereof, wherein B comprises an element such as Y, La, Pr, Nd, Pm, Eu, Gd, Th, Dy, Ho, Er, Tm, Yb, Lu, Sc, In, Tl, Mg, Ca, Sr, Ba, Li, Na, K, Rb, Cs, or combinations thereof, and wherein x, y, and z indicate the stoichiometry of the third material 110, e.g., the amount of the elements A and B, and the amount of oxygen O in the third material 110, for example.

In this embodiment, in some applications, the dielectric material 104 comprises a single layer of an insulating material comprised of AₓB_{y}O_{z}, wherein B comprises at least one element comprising In, Tl, Mg, Ca, Ba, Li, Na, K, Rb, or Cs. Element B may also comprise one or more of the elements In, Tl, Mg, Ca, Ba, Li, Na, K, Rb, or Cs combined with one or more other elements from Group IA, IIA, IIIA, IIIB, or the Lanthanide series, such as Y, La, Pr, Nd, Pm, Eu, Gd, Th, Dy, Ho, Er, Tm, Yb, Lu, Sc, In, Tl, Mg, Ca, Sr, Ba, Li, Na, K, Rb, Cs, or combinations thereof, in this embodiment.

The various material layers of the dielectric material 104 may be deposited using chemical vapor deposition (CVD), physical vapor deposition (PVD), atomic layer deposition (ALD), other deposition methods, or combinations thereof, for example.

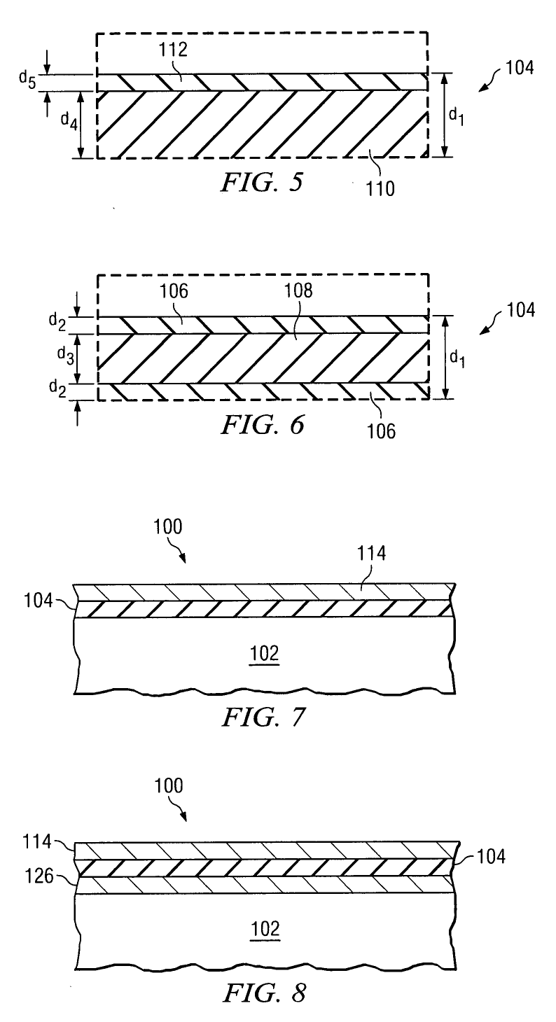

In a fourth embodiment, the high k dielectric material 104 comprises a fourth material 112 disposed over the third material 110, as shown in FIG. 5 in a more detailed view. The third material 110 preferably comprises a material comprising AₓB_{y}O_{z} as described for the third embodiment, for example. The third material 110 preferably comprises a thickness d₄ of less than about 200 Angstroms in this embodiment. The fourth material 112 preferably comprises a thickness d₅ of about 20 Angstroms or less. The fourth material 112 preferably comprises an oxide of a Group IIIA element, for example, in some embodiments. The fourth material 112 preferably comprises Al₂O₃, for example, in some embodiments. Alternatively, the fourth material 112 may comprise other materials and dimensions. The third material 110 may comprise a first insulating material, and the fourth material 112 may comprise a second insulating material disposed over the first insulating material, for example.

FIG. 6 shows a more detailed view of the high k dielectric material 104 of FIG. 1 in accordance with a fifth embodiment that includes a first layer of the first material 106 formed directly over, abutting, and adjacent to the workpiece 102, a second layer of the second material 108 disposed over the first layer of the first material 106, and a third layer of the first material 106 disposed over the second layer of the second material 108 in accordance with a preferred embodiment of the present invention. The first material 106 and the second material 108 preferably comprise the same materials and dimensions as described for the first embodiment, for example.

In the embodiments shown in FIGS. 2, 3, and 6, at least some combining of the first and second materials 106 and 108 may occur when depositing or forming the first and/or second materials 106 and 108. The first and second material 106 and 108 may react chemically during the deposition process of the first material 106 and/or the second material 108, for example. Thus, as a result, an interface region (not shown in the drawings) may form where the first material 106 and the second material 108 abut and are adjacent one another, wherein the interface region comprises the composition AₓB_{y}O_{z}; e.g., the composition of the third material 110. In the embodiment shown in FIG. 6, two interface regions may form, one at the top of, and one at the bottom of, the second material 108 (not shown). Alternatively, the first and second materials 106 and 108 may completely combine during the deposition or forming process of the first and second materials 106 and 108, forming the structure shown in FIG. 4 comprising a single substantially homogeneous material layer comprised of the third material 110, comprising a composition AₓB_{y}O_{z}, for example.

In some embodiments, the dielectric material 104 preferably does not comprise silicon. In other embodiments, the dielectric material 104 preferably does not comprise nitrogen or a nitride material.

Next, a layer of conductive material 114 is deposited over the high k dielectric material 104. FIG. 7 shows the semiconductor device of FIG. 1 after a layer of conductive material 114 has been formed over the high k dielectric material 104. The conductive material 114 preferably comprises a P type material, for example, in accordance with embodiments of the present invention. The conductive material 114 may comprise a gate material; an electrode material, or a capacitor plate material, as examples, although the novel high k dielectric material 104 may also be used in other structures. The conductive material 114 preferably comprises Ru, RuO₂, Ir, IrO₂, Pt, Os, OSO₂, Re, W, Mo, C, MoₓO_{y}N_{z}, WₓO_{y}N_{z}, IrₓSi_{y}, RuₓSi_{y}, PtₓSi_{y}, MoₓSi_{y}, WₓSi_{y}, TaCₓO_{y}N_{z}, NbCₓO_{y}N_{z}, or combinations or multiple layers thereof, wherein x and y indicate the stoichiometry of the elements of the conductive material 114, as examples, although alternatively, the conductive material 114 may comprise other materials. The conductive material 114 may be formed using metal oxide chemical vapor deposition (MOCVD), PVD, ALD, other deposition methods, or combinations thereof, for example.

In some embodiments, a conductive material 126 may also be disposed beneath the high k dielectric material, as shown in FIG. 8. For example, in this embodiment, the workpiece 102 may include a conductive material 126 disposed at a top surface thereof. Before forming the high k dielectric material 104, the conductive material 126 may be deposited over the workpiece 102, for example. The conductive material 126 preferably comprises similar materials and dimensions as previously described for conductive material 114, for example, although the conductive material 126 may comprise other materials and dimensions. The conductive material 126 may comprise the same or different materials and thicknesses as the material and thickness of the conductive material 114, for example. Conductive material 126 may comprise a bottom capacitor plate, and conductive material 114 may comprise a top capacitor plate, for example.

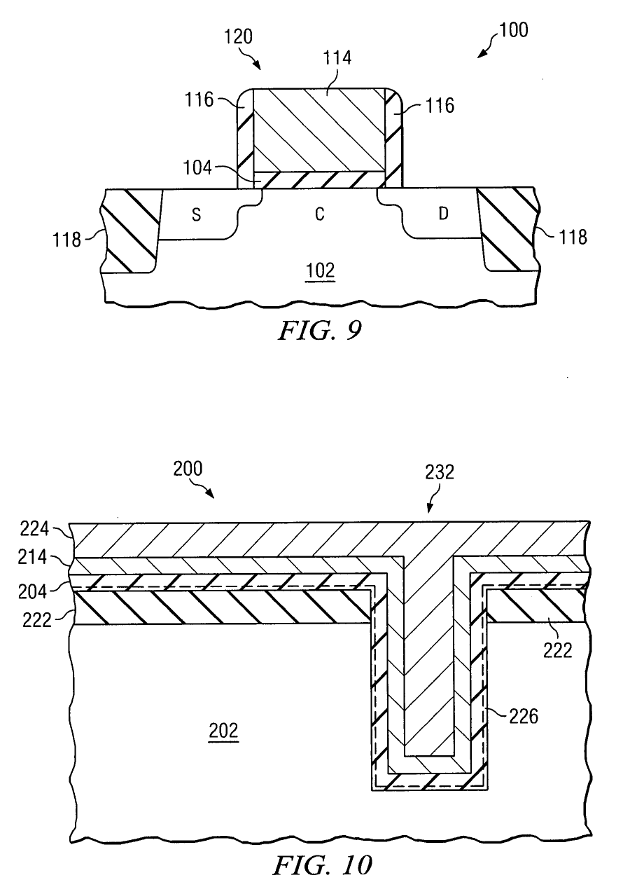

The material layers 130, 128, 126, and 124 may then be patterned using lithography to form transistors or capacitors from at least the electrode materials 114 and/or 126 and the dielectric layer 104 (not shown in FIGS. 7 and 8; see FIGS. 9 through 12 which will be described later herein).

The novel methods and structures described herein are shown implemented in a planar structure in FIGS. 2 through 8. The novel methods and structures of embodiments of the present invention may also be implemented in non-planar structures, for example.

Embodiments of the present invention include the novel dielectric materials 104 and electrode materials 114 and 126, and also methods of manufacturing semiconductor devices 100 using the novel dielectric materials 104 and electrode materials 114 and 126 described herein.

FIG. 9 shows a cross-sectional view of a semiconductor device 100 wherein the novel high k dielectric material 104, electrode 114 materials, and processing methods of embodiments of the present invention are implemented in a transistor 120 structure. Like materials and processes are preferably used to describe FIG. 9 as were used with reference to FIGS. 1 through 8, and to avoid repetition, each element number and processing step in FIG. 9 will not necessarily be described again herein.

The high k dielectric material 104 is implemented as a gate dielectric material 104, and the conductive material 114 is implemented as a transistor gate 114. The transistor 120 includes a gate dielectric material 104 comprising the novel high k dielectric material layer 104 described herein and a gate electrode 114 comprising conductive material 114 formed over the high k dielectric material layer 104. Source and drain regions S and D are formed proximate the gate electrode 114 in the workpiece 102, and a channel region C is disposed between the source and drain regions S and D in the workpiece 102. The transistor 120 may be separated from adjacent devices by shallow trench isolation (STI) regions 118 formed in the workpiece 102, and insulating sidewall spacers 116 may be formed on sidewalls of the gate electrode 114 and the gate dielectric 104, as shown.

Advantageously, because of the novel materials of the gate dielectric material 104, the P type gate electrode 114 has reduced Fermi-level pinning, because the larger atoms of the dopant or element B within the gate dielectric material 104 reduces the number of charged oxygen vacancies in the gate dielectric material 104, which reduces the Fermi-level pinning. Thus, a desired threshold voltage of the transistor 120 can be achieved.

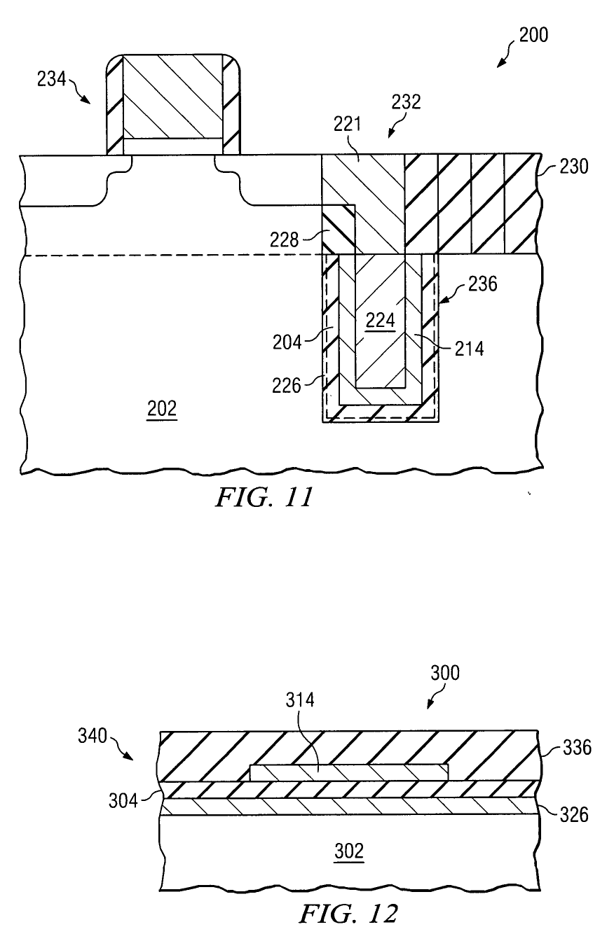

FIGS. 10 and 11 show cross-sectional views of a semiconductor device 200 at various stages of manufacturing, wherein the novel processing methods, high k dielectric material 204, and electrode materials 214 and 226 of embodiments of the present invention are implemented in a DRAM structure. Like numerals are used for the various elements that were described in FIGS. 1 through 9. To avoid repetition, each reference number shown in FIGS. 10 and 11 is not described again in detail herein. Rather, similar materials x04, x06, x08, etc. are preferably used for the various material layers shown as were used to describe FIGS. 1 through 9, where x=1 in FIGS. 1 through 9 and x=2 in FIGS. 10 and 11.

To form a DRAM memory cell 236 comprising a storage capacitor utilizing the novel high k dielectric material 204 of embodiments of the present invention, a sacrificial material 222 comprising an insulator such as a hard mask material is deposited over a workpiece 202, and deep trenches 232 are formed in the sacrificial material 222 and the workpiece 202. An optional conductive material 226 may be formed over the patterned workpiece 202 and sacrificial material 222, as shown in phantom in FIG. 10. The novel high k dielectric material layer 204 is formed over the patterned sacrificial material 222 and the workpiece 202. An electrode material comprising conductive material 214 is formed over the high k dielectric material layer 204, as shown. An additional electrode material 224 comprising polysilicon that may be doped with p-type doping, for example, or other semiconductor or conductive material may be deposited over the electrode material 214 to fill the trenches 232, as shown in FIG. 10.

Next, excess amounts of electrode materials 214 and 224 and dielectric material 204 are removed from over the top surface of the workpiece 202, e.g., using a chemical mechanical polish (CMP) process and/or etch process. The materials 214 and 224, and high k dielectric material layer 204 are also recessed below the top surface of the workpiece 202, for example. The sacrificial material 222 is also removed, as shown in FIG. 11.

An oxide collar 228 may be formed by thermal oxidation of exposed portions of the trench 232 sidewalls. The trench 232 may then be filled with a conductor such as polysilicon 221. Both the polysilicon 221 and the oxide collar 228 are then etched back to expose a sidewall portion of the workpiece 202 which will form an interface between an access transistor 234 and the capacitor 236 formed in the deep trench 232 in the workpiece 202, for example.

After the collar 228 is etched back, a buried strap 221 may be formed at the top of the trench 232 by deposition of a conductive material, such as doped polysilicon. Regions 224 and 221 comprising polysilicon are preferably doped with a dopant such as arsenic or phosphorus, for example. Alternatively, regions 224 and 221 may comprise a conductive material other than polysilicon (e.g., a metal).

The strap material 221 and the workpiece 202 may then be patterned and etched to form STI regions 230. The STI regions 230 may be filled with an insulator such as an oxide deposited by a high density plasma process (i.e., HDP oxide). The access transistor 234 may then be formed to create the structure shown in FIG. 11.

If the optional conductive material 226 lining the trench 232 is not included, the workpiece 202 proximate the high k dielectric material layer 204 lining the deep trench 232 comprises a first capacitor plate. If the optional conductive material 226 is included, the conductive material 226 and the workpiece 202 proximate the high k dielectric material layer 204 lining the deep trench 232 comprises the first capacitor plate. The high k dielectric material layer 204 comprises a capacitor dielectric, and materials 214 and 224 comprise a second capacitor plate of the deep trench storage capacitor of the DRAM memory cell 236. The access transistor 234 is used to read or write to the DRAM memory cell 236, e.g., by the electrical connection established by the strap 221 to a source or drain of the transistor 234 near the top of the deep trench 232, for example.

FIG. 12 shows a cross-sectional view of a semiconductor device 300, wherein the novel processing methods, high k dielectric materials 304, and electrode materials 314 and 326 of embodiments of the present invention are implemented in a metal-insulator-metal (MIM) capacitor 340, for example. Again, to avoid repetition, like numerals are used for the various elements that were used to describe the previous figures, and to avoid repetition, each reference number shown in FIG. 12 is not described again in detail herein.

To form the MIM capacitor 340, a bottom capacitor plate 326 is formed over a workpiece 302. The bottom capacitor plate 326 may be formed in an insulating material (not shown) that may comprise an inter-level dielectric layer (ILD), for example. The bottom capacitor plate 326 may include liners and barrier layers, for example, not shown.

The novel high k dielectric material 304 described with reference to FIGS. 1 through 11 is formed over the bottom plate 326. A conductive material 314 comprising an electrode material 314 is formed over the dielectric material 304, as shown in FIG. 12, and the electrode material 314 is patterned to form a top capacitor plate.

An additional insulating material 336 may be deposited over the top capacitor plate 314, and the insulating material 336 may be patterned with patterns for contacts (not shown) that will make electrical contact to the top plate 314 and the underlying bottom plate 326, respectively. The insulating material 336 may be filled in later with a conductive material to form the contacts in the patterns, for example, not shown.

Thus, in FIG. 12, a capacitor 340 is formed that includes the two conductive plates 326 and 314 separated by an insulator which comprises the novel high k dielectric material 304 and the novel electrode material described herein for the bottom plate 326 and the top plate 314 in accordance with embodiments of the present invention. The capacitor 340 may be formed in a front-end-of the line (FEOL), or portions of the capacitor 340 may be formed in a back-end-of the line (BEOL), for example. One or both of the capacitor plates 326 and 314 may be formed in a metallization layer of the semiconductor device 300, for example. Capacitors such as the capacitor 340 shown in FIG. 12 may be used in filters, in analog-to-digital converters, memory devices, control applications, and many other types of applications, for example.

Embodiments of the present invention may also be implemented in other structures that require a dielectric material. For example, the novel processing methods, high k dielectric material layers 104, 204, and 304, and electrode materials 114, 214, and 314 described herein may be implemented in planar transistors, vertical transistors, planar capacitors, stacked capacitors, vertical capacitors, deep or shallow trench capacitors, and other devices. Embodiments of the present invention may be implemented in stacked capacitors where both plates reside above a substrate or workpiece, for example.

Advantages of embodiments of the present invention include providing novel methods and structures having a high dielectric constant or k value. The high k dielectric materials 104, 204, and 304 described herein advantageously may have a dielectric constant or k value of about 10 or greater in some embodiments, and more preferably have a dielectric constant of greater than 20 in other embodiments, for example. The amount of Fermi-level pinning of the conductive material 114, 214, and 314 is reduced by the formation of a high k dielectric material 104, 204, and 304 that includes at least one dopant or element B having a larger cationic radius than atoms of a tetravalent element A oxide in the high k dielectric material 104, 204, and 304. The Fermi-level pinning effect is reduced by the introduction of charged oxygen vacancies by the use of element A in the dielectric material 104, 204, and 304, and by the reduction of the charged oxygen vacancies by the use of element B in the dielectric material 104, 204, and 304. Thus, desired threshold voltages, work functions, and dielectric constant values may be achieved in the devices the novel dielectric material 104, 204, and 304 are used in, for example.

Although embodiments of the present invention and their advantages have been described in detail, it should be understood that various changes, substitutions and alterations can be made herein without departing from the spirit and scope of the invention as defined by the appended claims. For example, it will be readily understood by those skilled in the art that many of the features, functions, processes, and materials described herein may be varied while remaining within the scope of the present invention. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of fabricating a semiconductor device, the method comprising:
providing a workpiece; and
forming a dielectric material over the workpiece, wherein forming the dielectric material comprises forming a first layer of a first material and forming a second layer of a second material, the first material comprising AO₂, wherein A comprises at least one Group IVB element, and the second material comprising BₓO_{y} wherein B comprises at least one Group 1A, IIA, IIIA, IIIB, or Lanthanide series element.

2. The method according to claim 1, wherein forming the dielectric material comprises first, forming the first layer of the first material over the workpiece, and second, forming the second layer of the second material over the first layer of the first material; or, first, forming the second layer of the second material over the workpiece, and second, forming the first layer of the first material over the second layer of the second material.

3. The method according to claim 1, wherein forming the first layer of the first material and forming the second layer of the second material comprise forming a single substantially homogeneous material layer comprising a composition AₓB_{y}O_{z}.

4. The method according to claim 1, wherein forming the first layer of the first material and forming the second layer of the second material comprise forming material layers having a thickness of about 200 Angstroms or less.

5. The method according to claim 1, wherein the second layer of the second material is doped with the at least one element B, wherein the second layer of the second material comprises an oxide of the at least one element B, or combinations thereof.

6. The method according to claim 1, wherein forming the dielectric material comprises: forming a first layer of a first material wherein the element A introduces charged oxygen vacancies into the dielectric material; and forming a second layer of a second material wherein the element B reduces the charged oxygen vacancies in the dielectric material

7. A method of fabricating a semiconductor device, the method comprising:
providing a workpiece; and
forming a dielectric material over the workpiece, the dielectric material comprising an insulating material comprised of AₓB_{y}O_{z}, wherein A comprises at least one Group IVB element, and wherein B comprises at least one element comprising In, Tl, Mg, Ca, Ba, Li, Na, K, Rb, or Cs, or wherein B comprises one or more of the elements In, Tl, Mg, Ca, Ba, Li, Na, K, Rb, or Cs combined with one or more other elements from Group IA, IIA, IIIA, IIIB, or Lanthanide series.

8. The method according to claim 7, wherein forming the dielectric material comprises forming a material that does not contain nitrogen.

9. The method according to claim 7, wherein forming the dielectric material comprises forming a material that does not contain silicon.

10. The method according to claim 7, further comprising forming a conductive material over and/or under the dielectric material, and forming a transistor or a capacitor from at least the conductive material and the dielectric material.

11. The method according to claim 7, wherein forming the dielectric material comprises forming a dielectric material having a dielectric constant of about 10 or greater.

12. The method according to claim 7, wherein providing the workpiece comprises providing a workpiece comprising GaAs, InP, InSb, Ge, GaP, GaN, or ZnS, and wherein forming the dielectric material comprises forming In, Tl, Ba, Na, K, Rb, or Cs.

13. A semiconductor device, comprising:
a workpiece; and
a dielectric material disposed over the workpiece, the dielectric material comprising a first layer of a first material and a second layer of a second material, the first material comprising AO₂, wherein A comprises at least one Group IVB element, the second material comprising BₓO_{y} and wherein B comprises at least one Group 1A, IIA, IIIA, IIIB, or Lanthanide series element.

14. The semiconductor device according to claim 13, wherein the first layer of the first material is formed directly over and adjacent to the workpiece, and wherein the second layer of the second material is formed directly over and adjacent to the first layer of the first material.

15. The semiconductor device according to claim 14, further comprising a third layer of the first material disposed over the second layer of the second material.

16. The semiconductor device according to claim 13, wherein the second layer of the second material is formed directly over and adjacent to the workpiece, and wherein the first layer of the first material is formed directly over and adjacent to the second layer of the second material.

17. The semiconductor device according to claim 13, wherein A comprises one or more elements comprising Zr, Hf, or Ti, and wherein B comprises one or more elements comprising Y, La, Pr, Nd, Pm, Eu, Gd, Tb, Dy, Ho, Er, Tm, Yb, Lu, Sc, In, Tl, Mg, Ca, Sr, Ba, Li, Na, K, Rb, or Cs.

18. The semiconductor device according to claim 13, further comprising an interface region comprising a composition AₓB_{y}O_{z} disposed between the first layer of the first material and the second layer of the second material.

19. A semiconductor device, comprising:
a workpiece; and
a dielectric material disposed over the workpiece, the dielectric material comprising a first layer of a first material disposed over the workpiece, a second layer of a second material disposed over the first layer of the first material, and a third layer of the first material disposed over the second layer of the second material, wherein the first material comprises AO₂, wherein A comprises at least one tetravalent element, wherein the second material comprises BₓO_{y} and wherein B comprises at least one monovalent element, divalent element, or trivalent element.

20. The semiconductor device according to claim 19, wherein B comprises an element having an atom having a cationic radius comprising a first size, wherein A comprises an element having an atom having a cationic radius comprising a second size, wherein the first size is greater than the second size.

21. The semiconductor device according to claim 19, further comprising a conductive material disposed over and/or under the dielectric material.

22. The semiconductor device according to claim 21, wherein the conductive material comprises a P type material.

23. The semiconductor device according to claim 21, wherein the conductive material comprises Ru, RuO₂, Ir, IrO₂, Pt, Os, OsO₂, Re, W, Mo, C, MoₓO_{y}N_{z}, WₓO_{y}N_{z}, RuₓSi_{y}, PtₓSi_{y}, MoₓSi_{y}, WₓSi_{y}, TaCₓO_{y}N_{z}, NbCₓO_{y}N_{z}, or combinations or multiple layers thereof.

24. A semiconductor device, comprising:
a workpiece; and
a dielectric material disposed over the workpiece, the dielectric material comprising an insulating material comprised of AₓB_{y}O_{z}, wherein A comprises at least one Group IVB element, and wherein B comprises at least one element comprising In, Tl, Mg, Ca, Ba, Li, Na, K, Rb, or Cs.

25. The semiconductor device according to claim 24, wherein B comprises one or more of the elements In, Tl, Mg, Ca, Ba, Li, Na, K, Rb, or Cs combined with one or more other elements from Group IA, IIA, IIIA, IIIB, or the Lanthanide series.

26. The semiconductor device according to claim 24, wherein the insulating material comprises a first insulating material, further comprising a second insulating material disposed over the first insulating material.

27. The semiconductor device according to claim 26, wherein the second insulating material comprises an oxide of a Group IIIA element.

28. The semiconductor device according to claim 26, wherein the second insulating material comprises about 20 Angstroms or less of Al₂O₃.
